(19) United States
(12) Patent Application Publication
(10) Pub. No.: US 2022/0302324 A1
(43) Pub. Date: Sep. 22, 2022

(54) HIGH-GAIN AMORPHOUS SELENIUM PHOTOMULTIPLIER

(71) Applicants: THE RESEARCH FOUNDATION FOR THE STATE UNIVERSITY OF NEW YORK, Albany, NY (US); NEW YORK UNIVERSITY, New York, NY (US)

(72) Inventors: Amirhossein GOLDAN, Stony Brook, NY (US); Wei ZHAO, East Setauket, NY (US); Ayaskanta SAHU, Brooklyn, NY (US)

(73) Assignees: THE RESEARCH FOUNDATION FOR THE STATE UNIVERSITY OF NEW YORK, Albany, NY (US); NEW YORK UNIVERSITY, New York, NY (US)

(21) Appl. No.: 17/642,471

(22) PCT Filed: Sep. 11, 2020
(86) PCT No.: PCT/US2020/050311

§ 371 Date: Mar. 11, 2022

Related U.S. Application Data
(60) Provisional application No. 62/899,437, filed on Sep. 12, 2019.

(51) Int. Cl. H01L 31/0272; H01L 31/09; H01L 31/107

(52) U.S. Cl. CPC H01L 31/0272; H01L 31/095; H01L 31/107

(57) ABSTRACT

A photomultiplier containing a solid-state photoconductive film composed of amorphous selenium (a-Se) is provided. In the a-Se containing photomultiplier, a hole-blocking layer is provided that maximizes gain and maintains low dark conductivity. Also, the hole-blocking layer achieves reliable and repeatable impact ionization without irreversible breakdown. The hole-blocking layer is a non-insulating metal oxide having a dielectric constant (k) of greater than 10.

### CROSS REFERENCE TO RELATED APPLICATION

The present invention claims the benefit of U.S. Provisional Patent Application No. 62/899,437, filed Sep. 12, 2019, the entire content and disclosure of which is incorporated herein by reference.

### GOVERNMENT SUPPORT

This invention was made with government support under EB025300 awarded by the National Institutes of Health. The government has certain rights in the invention.

### TECHNICAL FIELD

The present invention relates to a photomultiplier, and more particularly, to a photomultiplier containing a solid-state photoconductive film composed of amorphous selenium (a-Se).

### BACKGROUND

Efficient sensing and imaging of low-light signals down to the single photon level with a true solid-state photomultiplier has been a longstanding quest with a wide range of applications in astronomy, spectroscopy, optical communication, medical imaging, and the rapidly developing field of quantum optics and quantum information science. However, still the most popular commercial detector for low-light detection, and to achieve high dynamic range and linear mode operation, is a vacuum photomultiplier tube (PMT). PMTs operate on the basis of the photoelectric effect.

An electron can be promoted from valence band to vacuum level by an energetic photon and subsequently multiplied by dynodes and then collected by the anode. The main advantages of PMTs are very high-gain (typically 10⁵-10⁸) and low excess noise. However, PMTs are expensive, bulky, fragile, cannot operate under magnetic fields, have poor quantum efficiency in the visible spectrum, cannot operate in the infrared spectral region, cannot be pixelated into a 2D imaging array, and are not suitable for fast-timing applications (such as recent advanced fields in picosecond time-of-flight sensing).

Crystalline Silicon (c-Si) based avalanche photodiodes (reverse-biased p-n or p-i-n junction devices) also amplify photogenerated carriers via the impact ionization process. The difference is that in PMTs only electrons exist and are multiplied highly deterministically by the dynodes, but in crystalline semiconductors both electrons and holes are capable of experiencing impact ionization avalanche within the high electric field region. The latter impact ionization process is highly stochastic and leads to “excess noise” at high-gains. The fluctuations in the avalanche gain get progressively worse as the multiplication factor M is increased in avalanche photodiodes (APDs) by raising the electric field F. According to the McIntyre theory, the slope of M versus F is a strong function of the ratio of the two carriers' ionization rates k, where 1≤k<0. The high k-value in crystalline semiconductors contributes to the uniformity and yield issues in APDs.

The concept of band-structure engineering, using multi-gain stage semiconductor heterojunctions, was proposed in the 80s to ensure that only one carrier type (either electrons or holes) undergoes impact ionization, and thus, resulting in a more deterministic ionization behavior. In conventional APDs, carriers undergo a highly stochastic impact ionization process with a uniform probability in a constant high electric field region. By utilizing the conduction-band discontinuity of a heterojunction, the probability of ionization spikes just after an electron enters a narrow-bandgap semiconductor from a wider-bandgap semiconductor, thereby mimicking the behavior of a dynode in a PMT. However, with no incontrovertible evidence that such ideal modification of the ionization properties was possible to yield k˜0, and also because of the very low-gain achieved with these multi-stage heterojunctions at the optimal signal-to-noise ratio (SNR) with low excess noise, interest faded in the area of band-structure engineering before truly compelling results surfaced.

Another important development which was the closest solid-state device to mimic the behavior of a classical PMT was the Rockwell Si-based SSPM with noise-free non-Markov branching and F=1. Conventionally, carriers in APDs undergo ballistic impact ionization through a process called Markov (i.e., memoryless) branching. The carriers travel such a short distance (and for a very short time) for the next impact ionization that the avalanche process is independent of the history of phonon scattering (and the history of the steps required to build enough kinetic energy for impact ionization). However, carriers in Si SSPM experience a much smaller electric field, and thus, they must be accelerated over a finite time period before acquiring enough kinetic energy for the next impact ionization event. This “delay time” is expected to reduce (and potentially eliminate) the excess noise (i.e., excess noise factor ˜1) in such devices because the multiple scattering events and the associated acceleration and deceleration causes averaging of the distance traveled over the finite delay time before impact ionization. Thus, the history of phonon scattering and energy/momentum relaxation events play a part in a non-Markov branching process in SSPM which results in internal averaging of the stochastic process to yield noise-free deterministic gain. The Si SSPM is an impurity-band avalanche device which is operated at cryogenic temperatures (i.e., cooled to ˜5 K) and can count individual photons with wavelengths between 0.4 and 28 μm, making it an important device for use in low-background, near- to mid-IR detection applications. The device also has a very high single-carrier impact ionization gain of up to 105 conduction electrons. The avalanche impact ionization process is noiseless in SSPMs with F=1. The SSPM is, however, very difficult to fabricate, has very low yield to ensure k=0, and operates at cryogenic temperatures which severely limited its application, and thus, the technology was ultimately forgotten soon after its conception.

### SUMMARY

A photomultiplier containing a solid-state photoconductive film composed of amorphous selenium (a-Se) is provided. In the a-Se containing photomultiplier, a hole-blocking layer is provided that maximizes gain and maintains low dark conductivity. Also, the hole-blocking layer achieves reliable and repeatable impact ionization without irreversible breakdown. Further, the a-Se-containing photomultiplier has low light scattering due to the reduced number of layers that constituent the a-Se-containing photomultiplier.

The hole-blocking layer is a non-insulating metal oxide having a high-dielectric constant (k). By “high-k” it is meant that the metal oxide has a dielectric constant, as measured in a vacuum, of greater than 10. The high-k metal oxide hole-blocking layer provides improvements as compared to an equivalent a-Se-containing photomultiplier in which the high-k hole-blocking layer is replaced with one of an insulating hole-blocking layer, a non-insulating hole-blocking layer which is nonstoichiometric, or a non-insulating hole-blocking layer which is stoichiometric but has a lower dielectric constant than the dielectric constant than the high-k hole-blocking layer.

In one aspect of the present invention, a photomultiplier having a high-gain is provided. By “high-gain” it is meant that the photomultiplier has a gain of 100 or greater. The photomultiplier of the present application also exhibits a low dark current density. By “low dark current density” it is a dark current density of 1000 pA/cm² or less, as measured at the on-set of avalanche.

In one embodiment of the present invention, the photomultiplier includes an electron-blocking layer located on a first electrode. An amorphous selenium solid-state photoconductive film is located on the electron-blocking layer. A hole-blocking layer is located on the amorphous selenium solid-state photoconductive film. In accordance with the present invention, the hole-blocking layer includes a non-insulating metal oxide. A second electrode is located on the hole-blocking layer. In some embodiments, the photomultiplier of the present invention includes a passivation buffer layer sandwiched between the amorphous selenium solid-state photoconductive film and the hole-blocking layer.

In some embodiments of the present invention, the electron-blocking layer is in direct physical contact with a surface of the first electrode, the amorphous selenium film is in direct physical contact with a surface of the electron-blocking layer, the hole-blocking layer is in direct physical contact with a surface of the amorphous selenium film, and the second electrode is in direct physical contact with a surface of the hole-blocking layer. In other embodiments of the present invention, the electron-blocking layer is in direct physical contact with a surface of the first electrode, the amorphous selenium film is in direct physical contact with a surface of the electron-blocking layer, the passivation buffer layer is in direct physical contact with a surface of the amorphous selenium film, the hole-blocking layer is in direct physical contact with a surface of the passivation buffer layer, and the second electrode is in direct physical contact with a surface of the hole-blocking layer.

In another aspect of the present invention, an apparatus such as, for example, a photodetector or imager, is provided. The apparatus of the present invention includes at least one photomultiplier that includes an electron-blocking layer located on a first electrode, an amorphous selenium solid-state photoconductive film located on the electron-blocking layer, a hole-blocking layer located on the amorphous selenium photoconductive film, wherein the hole-blocking layer comprises a non-insulating metal oxide, and a second electrode located on the hole-blocking layer.

In a further aspect of the present invention, a method of forming a photomultiplier is provided. In one embodiment, the method includes forming an electron-blocking layer located on a first electrode. An amorphous selenium solid-state photoconductive film is formed on the electron-blocking layer. A hole-blocking layer is formed on the amorphous selenium solid-state photoconductive film. In accordance with the present invention, the hole-blocking layer comprises a non-insulating metal oxide. A second electrode is the formed on the hole-blocking layer.

In one embodiment, the hole-blocking layer is formed by preparing a solution processed material composed of metal oxide nanocrystals or a perovskite. Next, the solution processed material is deposited, at a temperature less than a crystallization on-set temperature for selenium, on a surface of the amorphous selenium solid-state photoconductive film.

### BRIEF DESCRIPTION OF THE DRAWINGS

FIG. 1 is a cross sectional view of a high-gain a-Se photomultiplier in accordance with an embodiment of the present invention.

FIGS. 2A-2C are electric field plots inside various vertical a-Se photomultipliers containing different hole-blocking layers; FIG. 2A, not of the invention, uses a SiO₂ hole-blocking layer (k=4); FIG. 2B, of the invention, uses a CeO₂ quantum dot hole-blocking layer (k=28); and FIG. 2C, of the invention, uses a SrTiO₃ hole-blocking layer (k=300); note k=εᵣ).

FIG. 3 is a plot illustrating effective quantum efficiency for various a-Se photomultipliers containing different hole-blocking layers as mentioned in FIGS. 2A-2C using a 15 μm thick a-Se solid-state photoconductive film; the plot shows avalanche gain fields exceeding 80 V/αm and that highest gain is achieved using the SrTiO₃ hole-blocking layer.

FIG. 4A is cross sectional view and a corresponding FIB-SEM of an a-Se containing photomultiplier containing a CeO₂ quantum dot hole-blocking layer.

FIG. 4B is TEM micrograph of CeO₂ nanocrystals with an average size of 5.3 nm that are used in providing the CeO₂ quantum dot hole-blocking layer shown in FIG. 4A.

FIG. 4C is a size distribution plot of the CeO₂ nanocrystals shown in FIG. 4B; the inset is a high resolution TEM of a single CeO₂ quantum dot with lattice fringe d-spacing of 0.316 nm, corresponding to the (111) plane of cubic fluorite CeO₂.

FIG. 4D illustrates the working principle of the avalanche a-Se photomultiplier of FIG. 4A.

FIG. 5A is an XRD pattern of 14 nm CeO₂ quantum dots with bulk reference pattern of cubic fluorite crystal structure.

FIG. 5B is an XPS spectra of Ce 3d_{3/2} and Ce 3d_{5/2} deconvoluted using Gaussian-Lorentzian (Voight) function.

FIG. 5C is an absorbance plot of CeO₂ quantum dots using UV-Vis-NIR spectroscopy for 14 nm and 5.3 nm CeO₂ quantum dots.

FIGS. 5D-5E are Tauc plots for 14 nm and 5.3 nm CeO₂ quantum dots, respectively. The inset shown in FIG. 5D is a high resolution TEM micrograph of a single 14 nm CeO₂ quantum dot, while the inset shown in FIG. 5E is a high resolution TEM micrograph of a single 5.3 nm CeO₂ quantum dot.

FIG. 6A is graph showing the measured dark current transients of an a-Se (15 μm)/CeO₂ quantum dot (150 nm) device across a wide range of applied electrical currents.

FIG. 6B is a graph showing the measured dark current density of an a-Se containing photomultiplier in accordance with the present invention including a CeO₂ quantum dot hole-blocking layer.

FIG. 6C is a graph showing the measured photoresponse of devices with 40 nm and 150 nm CeO₂ quantum dot hole-blocking layers achieving an avalanche gain of 50 and 7, respectively; the inset is a schematic of an optical TOF experiment.

### DETAILED DESCRIPTION

The present invention will now be described in greater detail by referring to the following discussion and drawings that accompany the present invention. It is noted that the drawings of the present invention are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present invention. However, it will be appreciated by one of ordinary skill in the art that the various embodiments of the present invention may be practiced without these specific details. In other instances, well-known structures or processing steps have not been described in detail in order to avoid obscuring the present invention.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

Embodiments of the invention described herein provide a high-gain amorphous selenium photomultiplier and method of forming same. Embodiments of the invention use solution-processed nanocrystals/nanoparticles (including quantum-dots) and/or perovskites with high dielectric constants as hole-blocking layers to enable achieving high-gain in amorphous selenium. Embodiments of the invention enable the development of the first true solid-state photomultiplier and promises to revolutionize solid-state photodetection and imaging with applications in astronomy, spectroscopy, optical communication, medical imaging, and the rapidly developing field of quantum optics and quantum information science.

Amorphous selenium (a-Se) as a solid-state photoconductive film is poised to revolutionize photodetection through its unique avalanche multiplication process. The two key features of the avalanche phenomenon in a-Se are that first, only holes get hot and undergo impact ionization, as seen from the large difference between electron and hole impact ionization rates, and second, the avalanche process is noise-free and non-Markovian. In addition, a-Se is a large-area room-temperature semiconductor with a wide band gap and ultra-low leakage current even at high fields, and thus does not require cooling.

Although a-Se can ideally provide gains similar to PMTs, its avalanche gain has been severely limited as a solid-state detector structure due to (A) insulating hole-blocking layers (HBLs), or (B) non-insulating HBLs which are nonstoichiometric, or (C) non-insulating HBLs which are stoichiometric but have a low dielectric constant (i.e., 10 or less). The term “stoichiometric” is used herein to define a compound having its component elements present in the exact proportion by its formula.

Item A is inadequate because insulators cause trapped space-charge effect and polarization. Item B does not work efficiently because defect states in the HBL substantially enhance charge injection. Item C also limits the attainment of very high-gain because of the presence of field hot-spots close to electrode edges and corners. An alternative HBL is needed for an a-Se photomultiplier which can maximize gain and maintain low dark conductivity. Also, the alternative HBL should achieve reliable and repeatable impact ionization without irreversible breakdown.

In the present invention, a non-insulating n-type hole-blocking/electron-transporting layer (hereinafter “hole-blocking layer”) is provided that includes a non-insulating metal oxide. The non-insulating metal oxide has a dielectric constant of greater than 10, i.e., the non-insulating metal oxide is a high-k material. The non-insulating metal oxide that is used as the hole-blocking layer is substantially stoichiometric. By “substantially stoichiometric” it is meant that the non-insulating material oxide is entirely stoichiometric or within ±5% from entirely stoichiometric.

The use of such a hole-blocking layer in an a-Se containing photomultiplier provides a true solid-state alternative to the vacuum PMT. In the present invention, solution-processed metal oxide nanocrystals/nanoparticles or solution-processed perovskites are used in providing the hole-blocking layer. The solution processed material is deposited at a temperature that does not cause any crystallization (either surface or bulk) of the a-Se layer. Experimental results of the fabricated a-Se-containing photomultiplier containing a non-insulating metal oxide having a high-k as the hole-blocking layer show the lowest dark current density ever reported at avalanche electric fields, without defect states and oxygen vacancies. The use of low-temperature solution-processed material as hole-blocking layers substantially improves the performance of avalanche selenium devices and may finally end the long-standing quest of developing a solid-state photomultiplier that mimics the behavior of a classical PMT.

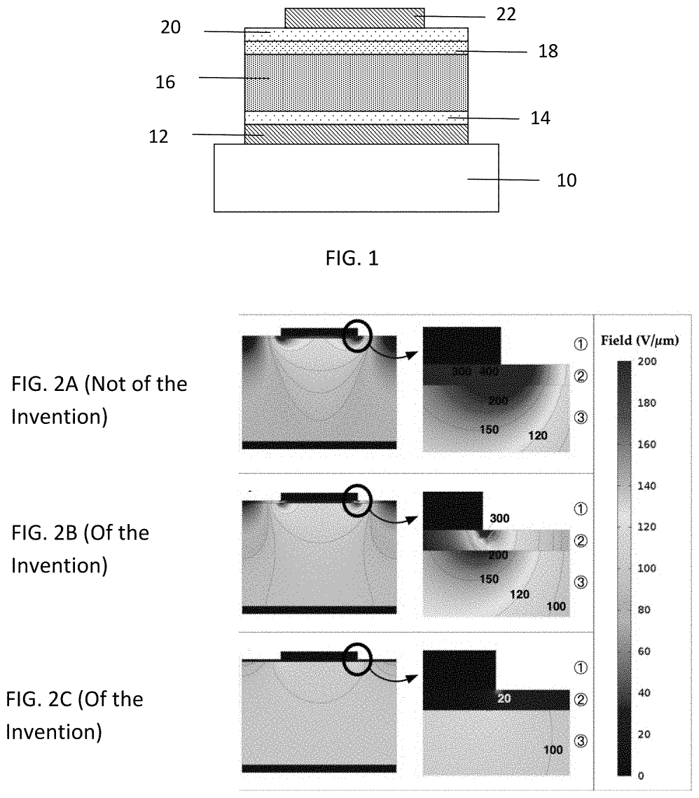

Referring now to FIG. 1, there is illustrated a high-gain, low dark current density a-Se photomultiplier in accordance with an embodiment of the present invention. The a-Se photomultiplier of FIG. 1 can be used as a component in a photodetector, an imager, a sensor or any other apparatus in which detection of photons is desired. The a-Se photomultiplier of FIG. 1 includes a substrate 10, a first electrode 12, an electron-blocking layer 14 (i.e., p-layer), an amorphous selenium solid-state photoconductive film 16 (i.e., i-layer), a passivation buffer layer 18, a hole-blocking layer 20 (i.e., n-layer), and a second electrode 22. In some embodiments, the passivation buffer layer 18 can be omitted. In some embodiments, substrate 10 can be omitted.

In the embodiment and as depicted in FIG. 1, the substrate 10, the first electrode 12, the electron-blocking layer 14, the amorphous selenium solid-state photoconductive film 16, the passivation buffer layer 18, the hole-blocking layer 20, and the second electrode 22 are vertically stacked on atop the other.

When present, substrate 10 is typically a transparent substrate such as, for example, a semiconductor substrate or a glass substrate. The semiconductor substrate includes at least one semiconductor material such as, for example, silicon.

The first electrode 12 can be composed of any transparent, conductive material including, for example, indium tin oxide (ITO). In some embodiments (not shown), the first electrode 12 can be present on an entirety of the substrate 10. In other embodiments, and as is depicted in FIG. 1, the first electrode 12 is present on a portion of the substrate 10. In some embodiments, the first electrode 12 can be in direct physical contact with, and thus form a material interface with, the substrate 10. The first electrode 12 can have a thickness from 10 nm to 1000 nm; although other thicknesses for the first electrode 12 are contemplated and can be used as the thickness of the first electrode 12. The first electrode 12 can be formed utilizing techniques well known to those skilled in the art. For example, the first electrode 12 can be formed utilizing a deposition process such as, for example, physical vapor deposition (PVD), atomic layer deposition (ALD), or plating. In some embodiments, a patterning process such as, for example, photolithography, can follow the deposition of the transparent, conductive material that provides the first electrode 12.

In some embodiments, the electron-blocking layer 14 can be a high-temperature, high field electron-blocking layer composed of a polymer such as, for example, parylene or polyimide (PI). In other embodiments, the electron-blocking layer 14 is composed of an inorganic electron blocking material such as, for example, arsenic triselenide (As₂Se₃) or nickel oxide (NiO). The electron-blocking layer 14 can have a thickness from 10 nm to 6000 nm; although other thicknesses for the electron-blocking layer 14 are contemplated and can be used as the thickness of the electron-blocking layer 14. The electron-blocking layer 14 can be formed utilizing techniques well known to those skilled in the art. For example, the electron-blocking layer 14 can be formed utilizing a deposition process such as, for example, chemical vapor deposition (CVD), plasma-plasma enhanced chemical vapor deposition (PECD), solution deposition, thermal evaporation or spin-on coating. The electron-blocking layer 14 is typically in direct physical contact with, and thus forms a material interface with, the first electrode 12.

The amorphous selenium solid-state photoconductive film 16 is a film of selenium that lacks any crystalline structure; while there can be local ordering of atoms in the amorphous selenium solid-state photoconductive film 16, no long term ordering is present. The amorphous selenium solid-state photoconductive film 16 can be doped (stabilized) or non-doped. Examples of dopants for the amorphous selenium solid-state photoconductive film 16 include, but are not limited to, arsenic, tellurium or chlorine. The dopant can be present in the amorphous selenium solid-state photoconductive film 16 in an amount from 0.1 atomic percent to 0.5 atomic percent. The amorphous selenium solid-state photoconductive film 16 can have a thickness from 0.5 μm to 100 μm; although other thicknesses for the amorphous selenium solid-state photoconductive film 16 are contemplated and can be used as the thickness of the amorphous selenium solid-state photoconductive film 16. The amorphous selenium solid-state photoconductive film 16 can be formed utilizing techniques well known to those skilled in the art. In one example, the amorphous selenium solid-state photoconductive film 16 can be formed by the thermal evaporation of stabilized vitreous selenium pellets. The amorphous selenium solid-state photoconductive film 16 is typically in direct physical contact with, and thus forms a material interface with, the electron-blocking layer 14.

When present, the passivation buffer layer 18 is composed of any material that protects the underlying amorphous selenium solid-state photoconductive film 16 from oxidation. In one example, the passivation buffer layer 18 can be composed of SiO₂. The passivation buffer layer 18 can have a thickness from 10 nm to 1000 nm; although other thicknesses for passivation buffer layer 18 are contemplated and can be used as the thickness of the passivation buffer layer 18. The passivation buffer layer 18 can be formed utilizing a deposition such as, for example, sputtering. In the present invention, the deposition of the passivation buffer layer 18 is performed utilizing conditions that do not crystallize any portion (i.e., surface or bulk) of the underlying amorphous selenium solid-state photoconductive film 16. As such, the amorphous selenium solid-state photoconductive film 16 remains entirely amorphous after the formation of the passivation buffer layer 18. The passivation buffer layer 18 is typically in direct physical contact with, and thus forms a material interface with, the amorphous selenium solid-state photoconductive film 16.

To provide high-gain and low dark current density to the device, the hole-blocking layer 20 comprises a non-insulating metal oxide. The non-insulating metal oxide that provides the hole-blocking layer 20 has a high-k (i.e., a dielectric constant of greater than 10). In some embodiments, the non-insulating metal oxide that provides the hole-blocking layer 20 has a dielectric constant of from greater than 10 to 100. In other embodiments, the non-insulating metal oxide that provides the hole-blocking layer 20 has a dielectric constant of greater than 10 up to 20,000. The non-insulating metal oxide that provides the hole-blocking layer 20 can be substantially stoichiometric, as defined above.

In one embodiment of the present invention, the non-insulating metal oxide that provides the hole-blocking layer 20 is composed of metal oxide nanocrystals/nanoparticles. The terms “nanocrystals” and “nanoparticles” are used interchangeably in the present invention. A nanocrystal/nanoparticle typically has a size that is less than 100 nm in diameter. The metal oxide nanocrystals can provide metal oxide quantum dots. Quantum dots are nanocrystals that demonstrate quantum confinement. Examples of metal oxides that can be used in the present invention as the metal oxide nanocrystals/nanoparticles include, but are not limited to, oxides of transition group metals of the Periodic Table of Elements. In one embodiment of the present invention, the metal oxide nanocrystals/nanoparticles that are used as the hole-blocking layer 20 comprise cerium oxide, CeO₂ quantum dots.

In other embodiments, the non-insulating metal oxide that provides the hole-blocking layer 20 is composed of a perovskite. A perovskite is a material that has a same crystal structure as the mineral calcium titanium oxide. Generally, perovskite have a chemical formula ABX₃ wherein A and B represent cations and X is an anion that bonds to both cations. Examples of perovskite that can be used in the present invention include, but are not limited to, strontium titanate (i.e., SrTiO₃) or barium titanate (BaTiO₃). In one embodiment, the perovskite that provides the electron hole-blocking layer 20 is SrTiO₃. The perovskite is nanocrystalline as well.

Notwithstanding the type of non-insulating metal oxide used in providing the hole-blocking layer 20, the hole-blocking layer 20 can have a thickness from 10 nm to 150 nm; although other thicknesses for hole-blocking layer 20 are contemplated and can be used as the thickness of the hole-blocking layer 20.

The hole-blocking layer 20 of the present invention is formed by first preparing a solution processed material comprised of metal oxide nanocrystals/nanoparticles or a perovskite, as defined above. The forming of the solution processed material includes preparing a colloidal dispersion of metal oxide nanocrystals/nanoparticles or a perovskite. The colloidal dispersion further includes a solvent or mixture of solvents. The term “colloidal dispersion” is used in the present invention to denote a heterogeneous system that is made up of a dispersed phase (i.e., the metal oxide or perovskite) and a dispersion medium (i.e., the solvent or mixtures of solvents). In a colloidal dispersion, one substance (i.e., the metal oxide or perovskite) is dispersed as fine particles in the dispersion medium (i.e., the solvent or solvent mixture). The solvent or mixtures of solvents thus includes a substance that disperses, but does not dissolve, the metal oxide or perovskite. Examples of solvents that can be used in formed the solution processed material includes, but are not limited to, organic solvents including, for example, hexane, octane, heptanes, decane, chloroform, or toluene. In one example, the solution used in providing the solution processed material includes a solvent mixture of hexane and octane.

The preparing of the colloidal dispersion of nanocrystals/nanoparticles or perovskite and solvent or mixture of solvents includes adding, in any order, the nanocrystals/nanoparticles or perovskite and the solvent or mixture of solvents. The metal oxide nanocrystals/nanoparticles can be prepared by techniques well known to those skilled in the art. Following the addition step, the mixture of metal oxide nanocrystals/nanoparticles or perovskite and solvent(s) is mixed under conditions to facilitate the preparation of a colloidal dispersion.

After preparing the solution process material, the solution processed material is deposited, at a temperature less than a crystallization on-set temperature for selenium, on a surface of the amorphous selenium solid-state photoconductive film 16. By “a temperature less than a crystallization on-set temperature for selenium” it is meant a temperature, e.g., 80° C. or less, in which the underlying layer of amorphous selenium solid-state photoconductive film 16 does not undergo any crystallization, either on the surface of the amorphous selenium solid-state photoconductive film 16 or in the bulk of the amorphous selenium solid-state photoconductive film 16. Thus, the amorphous selenium solid-state photoconductive film 16 remains entirely amorphous after the deposition of the solution processed material that provides the hole-blocking layer 20. In one embodiment, the deposition of the solution processed material that provides the hole-blocking layer 20 is performed at a temperature of 60° C. or less. In yet another embodiment, the deposition of the solution processed material that provides the hole-blocking layer 20 is performed at a nominal room temperature (i.e., a temperature from 20° C. to 30° C.).

The deposition of the solution processed material that provides the hole-blocking layer 20 can include any well known deposition technique including, but not limited to, spray coating, spin-coating, inkjet printing, doctor blading, roll-to-roll printing, dip coating, screen printing, drop casting, brush painting, stamp printing, zone casting, hollow pen writing, slot die coating, or solution shearing.

In some embodiments of the present invention, a ligand exchange process can be performed on the deposited solution processed material to provide the hole-blocking layer 20. The ligand exchange process includes substituting the native ligands used during the synthesis and deposition, with new organic and inorganic ligands; typically, but not necessarily always, the new organic and inorganic ligands are compact, short chain ligands. This ligand exchange process can be performed both pre- and post-deposition. Typical short chain ligands can be both organic such as ethanedithiol, ethyleneamine, pyridine, hydrazine or inorganic ligands such as sulfides, hydroxides, selenides, tellurides, thiocyanates, hydrosulfides etc.

The second electrode 22 can be composed of any transparent, conductive material including, for example, indium tin oxide (ITO). The transparent, conductive material that provides the second electrode 22 can be compositionally the same as, or compositionally different from, the transparent, conductive material that provides the first electrode 12. In one embodiment, both the first electrode 12 and the second electrode are composed of indium tin oxide. In some embodiments (not shown), the second electrode 22 can be present on an entirety of the hole-blocking layer 20. In other embodiments, and as is depicted in FIG. 1, the second electrode 22 is present on a portion of the hole-blocking layer 20. In some embodiments, the second electrode 22 can be in direct physical contact, and thus form a material interface with, the hole-blocking layer 20. The second electrode 22 can have a thickness from 10 nm to 1000 nm; although other thicknesses for the second electrode 22 are contemplated and can be used as the thickness of the second electrode 22. The second electrode 22 can be formed utilizing techniques well known to those skilled in the art. For example, the second electrode 22 can be formed utilizing a deposition process such as, for example, physical vapor deposition (PVD), atomic layer deposition (ALD), or plating. In some embodiments, a patterning process such as, for example, photolithography, can follow the deposition of the transparent, conductive material that provides the second electrode 22.

The following examples are provided to illustrate some aspects of the present invention. The present invention is however not limited by the following examples.

### Example I: Amorphous Selenium (a-Se) Photomultipliers Containing Different Hole-Blocking Layers

In this example, the electric field and effective quantum efficiency were investigated for various vertical a-Se photomultipliers containing different hole-blocking layers. Notably, the various vertical a-Se photomultipliers included amorphous selenium as photoconductive film 16, different hole-blocking layers 20 as defined below, and an indium tin oxide second electrode 22.

The different hole-blocking layers 20 included: for FIG. 2A (not of the invention) a 100 nm SiO₂ hole-blocking layer (k=4), for FIG. 2B, of the invention, a 100 nm CeO₂ quantum dot hole-blocking layer (k=28), for FIG. 2C, of the invention, a 100 nm SrTiO₃ hole-blocking layer (k=300); note k=εᵣ). The SiO₂ hole-blocking layer was deposited by sputtering, while the CeO₂ quantum dot hole-blocking layer and the SrTiO₃ hole-blocking layer were prepared by first providing a solution processed material and then depositing the solution processed material at a temperature less than a crystallization on-set temperature for selenium.

Referring now to FIGS. 2A, 2B and 2C, there is shown the electric field plots in the various a-Se photomulitipliers. Note that in all cases, the electric field inside the bulk is 100 V/μm. As shown in FIG. 2A, field hot-spots were present using a SiO₂ hole-blocking layer. In FIG. 2B, field hot-spots were present using a CeO₂ hole-blocking layer, although at a lesser degree than using the SiO₂ hole-blocking layer. For example, using the CeO₂ hole-blocking layer, the electric field in the vicinity of the electrode/oxide and oxide/a-Se interfaces reached 300 V/μm and 200 V/μm, respectively, when the bulk is biased at only 100 V/μm. As shown in FIG. 2C, field hot-spots are completely erased when using the SrTiO₃ hole-blocking layer.

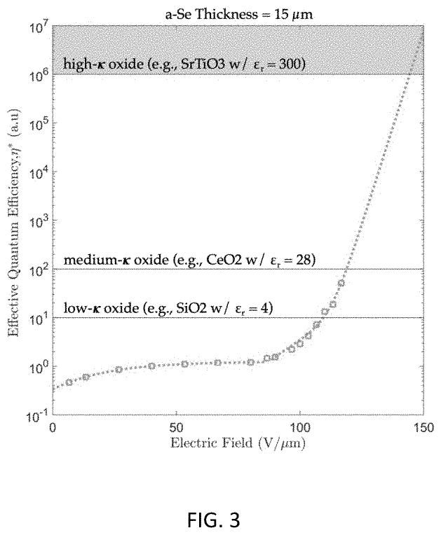

Referring now to FIG. 3, there is shown the effective quantum efficiency of the various a-Se photomulitipliers where avalanche gain is severely limited due to the presence of field hot-spots. However, high-gain of 106 was achieved using the SrTiO₃ hole-blocking layer.

### Example II: Investigation Using Solution Processed CeO₂ Quantum Dots as a Hole-Blocking Layer

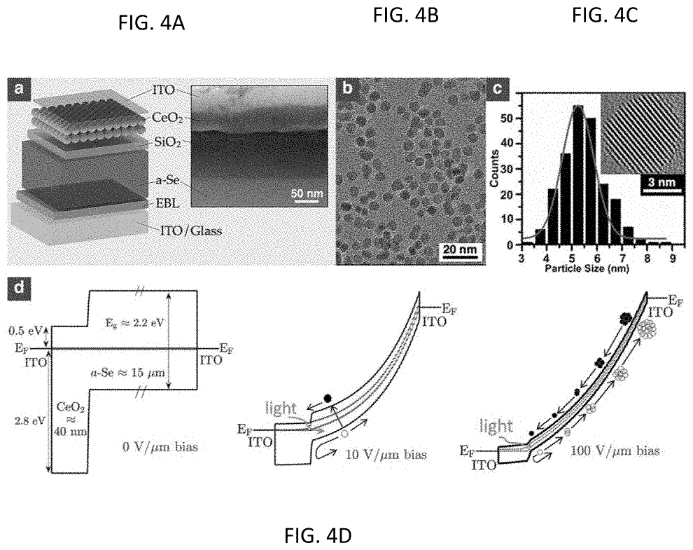

In this example, a solution-processed CeO₂ quantum dot layer having a large bandgap of 3.77 eV was deposited over a-Se photoconductor at room temperature without any surface or bulk crystallization. FIG. 4A depicts the schematic of the p-i-n structure and cross-sectional focused ion beam-scanning electron microscope (FIB-SEM) of the fabricated prototype showing the p-i-n and ITO electrode layers. At sizes below an exciton Bohr radius of 7-9 mm, CeO₂ quantum dots exhibit quantum confinements effects and a size tunable bandgap, further increasing the hole potential barrier beyond 2.8 eV. Many of the previously reported CeO₂ quantum dot syntheses involve high temperature calcination (500° C.-600° C.), that resulted in non-stoichiometric CeO₂ and were prone to morphological instability and uncontrolled agglomeration. Here, and in this example, a facile colloidal approach to obtain substantially stoichiometric non-agglomerated CeO₂ quantum dot that are surface-passivated by ligands in the quantum confinement regime from 14 nm down to 5.3 nm, demonstrating bandgaps ranging from 3.66 eV to 3.77 eV, respectively. Colloidal CeO₂ quantum dots were synthesized using a high temperature decomposition technique proposed by Runnerstrom et al. entitled “Colloidal Nanocrystals Films Reveal the Mechanism for Intermediate Room Temperature Proton Conductivity in Porous Ceramics”, J. Phys. Chem. C208, 122, 13624-13635.

FIG. 4B shows a transmission electron microscopy (TEM) image of an ensemble of fairly monodisperse quantum dots with an average size of 5.3±0.7 nm (FIG. 4C). The inset of FIG. 4C shows a high resolution TEM micrograph of a single CeO₂ quantum dot with 0.316 nm interplanar spacing measured from the lattice fringes, which corresponds to the (111) plane of cubic fluorite.

Device level simulations were performed using SILVACO TCAD (ATLAS version 5.25.1.R) to establish a clearer physical picture of light interaction in an a-Se avalanche photodetector with a bulk CeO₂ quantum dot hole-blocking layer. FIG. 4D shows the simulated energy band diagram for the detector structure at different electric fields, where transport shifts from the localized to extended states after the avalanche threshold voltage (≈80 V/μm) is crossed, leading to hole initiated avalanche gain.

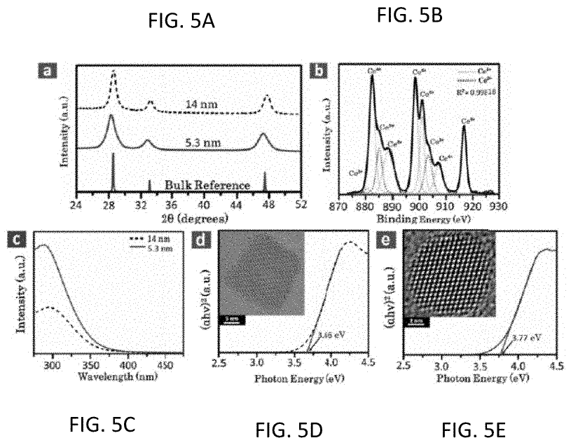

Powder X-ray diffraction patterns of CeO₂ quantum dots shown in FIG. 5A matches that of the cubic fluorite structure of CeO₂ with Scherrer broadening responsible for the broad peaks. As the average particle size increases from 5.3 nm to 14 nm, the diffraction peaks sharpen as expected. To elucidate the oxidation state and the stoichiometry of CeO₂, the Ce 3d emission spectra was studied using X-ray photoelectron spectroscopy (XPS) (FIG. 5B which shows the co-existence of both Ce⁴⁺ and Ce³⁺. Since the peaks of Ce³⁺ and Ce⁴⁺ approximately overlap with each other, the spectra in FIG. 5B was deconvoluted and hence the concentration of Ce³⁺ was estimated to be a non-trivial value of 18.5%, nearly 10%-20% lower than previously reported values of CeO₂ quantum dots synthesized through other methods. A large amount of Ce³⁺ in the crystal leads to oxygen vacancies and hence induce defect states in the quantum dots. In the colloidal approach of the present invention, the ligands are used to provide both colloidal stability as well as to passivate defects. Moreover, these surfactants can induce a quantum dot-ligand interface dipole that contributes to energy level shifts in valence band maximum, thus potentially increasing the hole barriers even further.

The bandgap of the as-synthesized CeO₂ quantum dots were measured through UV-Vis-NIR absorption spectra (FIG. 5C). The absorption spectra of quantum dots dispersed in carbon tetrachloride did not exhibit a distinct absorption peak at the band edge. Hence the bandgap was computed from the experimental data using Tauc plots which demonstrated that as the size of the quantum dots decreases from 14 nm to 5.3 nm, the optical direct bandgap increases from 3.66 eV to 3.77 eV (FIGS. 5D and 5E) as expected from quantum confinement effects.

Since, the colloidal dispersibility of as-synthesized quantum dots in this approach were enhanced by ligands, devices can be fabricated at room temperature using cheap deposition techniques such as inkjet printing or spin coating. The 5.3 nm CeO₂ quantum dots with a bandgap 7 of 3.77 eV were spun coat on a-Se substrates with 110 nm SiO₂ at room temperature to achieve 40 nm and 150 nm thick CeO₂ quantum dot layers.

The quality of the thin quantum dot film deposited from the inventive colloidal approach was compared to the precipitation method using custom-made CeO₂ quantum dots following the procedure in Arul et al entitled “Strong Quantum Confinement Effect In Nanocrystalline cerium oxide”, Mater. Lett. 2011, 65, 2635-2638. The colloidally synthesized CeO₂ quantum dots with ligands achieved uniform deposition without any micro-cracks, voids, and aggregation of quantum dots, clearly emphasizing the importance of suitable surfactants in achieving better colloidal dispersion for thin film fabrication.

As-synthesized CeO₂ quantum dots with long-chain ligands were exchanged with short-chain NH₄SCN ligands in the deposited thin film to increase the electronic coupling among quantum dots on the true solid-state device and the ligand exchange was tracked using Fourier Transform-Infrared Spectroscopy (FT-IR). The appearance of a distinct peak at 2048 cm⁻¹ post ligand exchange corresponding to NH₄SCN shows that nearly 88% of ligand exchange has occurred. It was concluded from XRD, that the solution processing of the present invention did not initiated any crystallization on a-Se.

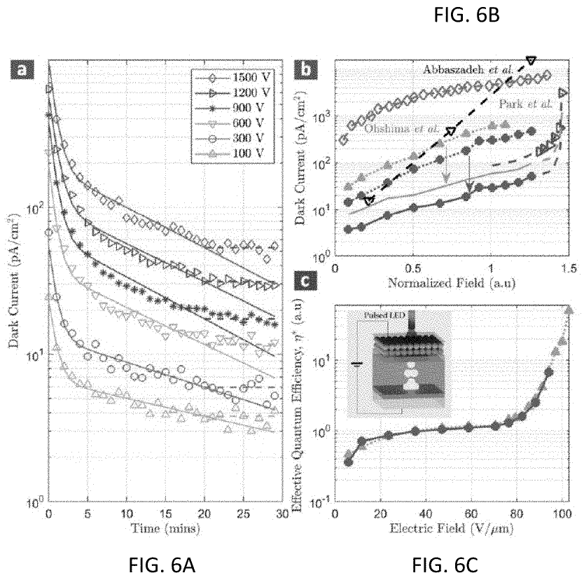

FIG. 6A shows the measured dark current density transients of the 150 nm thick CeO₂ quantum dot-based p-i-n device across a wide range of applied electric fields, E. In each case, the transients were fitted with a two-term exponential (solid line) until reaching a steady state (dashed line) after 25 minutes. The fast initial drop in dark current is due to injected carriers becoming trapped within the hole-blocking layer, reducing the effective E at the interface, while the second gradual decay to steady state equilibrium is due to the detrapping of bulk space charge.

FIG. 6B shows the measured dark current density of inventive devices (40 nm green and 150 nm blue) as a function of E at 1 minute (dotted line) and 30 minute (solid line) time points, comparing the transient and steady state dark current. At subavalanche fields (E<70 V/μm), the steady state dark current of the inventive device with 150 nm CeO₂ quantum dot layer was found to settle below 30 pA/cm². At the high fields required for avalanche gain, the dark current was measured to be extremely low, reaching approximately 50 pA/cm² at E=88 V/μm.

FIG. 6B also compares the dark current density for solid-state a-Se avalanche devices fabricated in an n-i-p sequence, adapted from Ohshima et al. entitled “Excess Noise in Amorphous Selenium Avalanche Photodiodes”, Appl. Phys., Part 2 1991, 30, L1071-L1074 and Abbaszadeh et al. entitled “Investigation of Hole-Blocking Contacts for High-Conversion-Gain Amorphous Selenium Detectors for X-Ray Imaging”, IEEE Trans., Electron Devices 2021, 59, 2403-2409. In each case, the measured steady state dark current after the onset of avalanche (E>70 V/μm), was at least two orders of magnitude lower than the solid-state n-i-p a-Se avalanche devices. Additionally, the dark current values from a vacuum HARP pickup tube capable of achieving gains or approximately 103, adapted are included for comparison. While no low field data is available for vacuum HARP devices, the results are extended (dashed line) utilizing an identical impact ionization curve as Park et al. entitled “Avalanche-type High Sensitive Image Pickup Tube using an a-Se photoconductive target”, Jpn. J. Appl. Phys. 2003, 42, L209-L211 showing the significant potential improvements in sensitivity at high fields if similar gains were reached with the inventive devices. Each of the adapted n-i-p HARP results shown in FIG. 6B utilized CeO₂ hole-blocking layer which were deposited via high temperature vacuum deposition. The CeO₂ films utilized in the n-i-p devices are incompatible with a p-i-n fabrication sequence, suffer from defect levels due to oxygen vacancies and generally exhibit worse performance as a function of increasing film thickness. Experimental results of the inventive p-i-n devices showed the lowest reported dark current density at avalanche electric fields with over 300% improvement than best-in-class solid state vertical devices and nearly 200% improvement over even the vacuum devices.

Unlike bulk CeO₂, the results provided by FIG. 6B show a substantial decrease in dark current with increasing CeO₂ film thickness, which can be hypothesized with the following possibilities: (i) the colloidal synthesis method induces only discrete localized defect levels on a few CeO₂ quantum dots at the surface as shown from the relatively low intensity Ce³⁺ peaks in the XPS spectrum. This result agrees with the fact that the formation energy of ‘intrinsic’ defects in quantum dots are typically much larger than in bulk, thus suppressing the formation of defects (ii) the presence of sparse, isolated defects in the thin film do not interact strongly with one another and form a continuous defect band within the bandgap, even upon increasing the thickness of the film. Most of the defects in these quantum dots are relegated to the surface and each quantum would have the defect level (if any at all) at a random energy state, generating a random dispersion of energy states with an extremely low density of states rather than a coherent band. (iii) Ammonium thiocyanate ligands may potentially passivate the surface defect states caused from oxygen vacancy through dative bonding. However, the significant reduction in dark current clearly promises the potential application of low temperature solution-processed quantum dots as hole-blocking layers.

FIG. 6C shows the photoresponse of devices with 40 nm (green) and 150 nm (blue) CeO₂ quantum dot hole-blocking layers achieving an avalanche gain of 50 and 7, respectively. The inset of FIG. 6C schematically represents the optical time-of-flight (TOF) photoconductivity experiments used to measure the photoresponse of each sample as a function of E. The effective quantum efficiency, η*, was measured over a wide range of electric fields (E=6-100 V/μm). At subavalanche fields, photogeneration efficiency is limited by geminate recombination, however as E increases, the likelihood of recombination decreases as the electron-hole pairs are pulled apart more efficiently, increasing η* until plateauing at unity, following the Onsager dissociation model. Once the avalanche threshold was crossed, η* increased rapidly as the drift mechanism of holes shifts from localized trap-limited mobility to an extended state band-like transport, causing holes to impact ionize, which frees additional EHPs, thus amplifying the signal current. The maximum applied field (E≈120 V/μm) prior to electrical breakdown resulted in an avalanche gain of ≈50.

In conclusion, this example demonstrates that the use of low-temperature solution-processed quantum dots as a hole-blocking layer can substantially improve the performance of p-i-n avalanche a-Se detectors and end the long-standing quest of developing a solid-state photomultiplier that mimics the behavior of a classical PMT.

Synthesis of CeO₂ Quantum Dots. All the chemicals were used as purchased without any purification. 5.3 nm CeO₂ colloidal quantum dots (QDs) were synthesized using a modified procedure proposed by Runnerstrom et al (See, J. Phys. Chem. C208, 122, 13624-13635). In a typical synthesis, 8 ml of oleylamine and 5 ml of 1-octadecene were added to 868.4 mg of Ce(NO₃)₃.6H₂O in a 250 ml round bottom three-neck flask at room temperature. The temperature was then raised to 80° C. and kept constant for 30 minutes to homogenize the reaction mixture. Subsequently, the temperature was again raised to and maintained at 250° C. for 2 hours resulting in decomposition of precursors and nucleation and growth of quantum dots. During the process, the stopper was punctured with a needle to avoid over-pressurization of the flask due to release of nitrogen dioxide (NO₂) gas during the decomposition of Ce(NO₃)₃. After 2 hours, a common surfactant, oleic acid (typically around 1 volume % of the reaction mixture) was added to improve colloidal stability and minimize agglomeration. The reaction mixture was then annealed at 250° C. further for 5 minutes and then air cooled to room temperature. Ethanol was added as an anti-solvent to the obtained reaction mixture and centrifuged at 8500 rpm for 5 minutes to crash out the quantum dots. The collected quantum dots were dispersed in 5 ml of hexane after which, oleic acid (around 10 volume % of the mixture) was added and stirred overnight. The process of purification was repeated 3 times using ethanol and re-dispersion in hexane. As-synthesized quantum dots were dispersed in an 8:2 solvent ratio of hexane and octane to form 30 mg/ml and 50 mg/ml colloidal dispersions for further use in thin film fabrication. To study the effect of quantum confinement, the larger sized CeO₂ colloidal quantum dots (around 14 nm) were synthesized following the procedure by Runnerstrom et al (See, J. Phys. Chem. C208, 122, 13624-13635). 40 mg of octadecylamine, 4.9 ml of oleylamine, and 5 ml of octadecene were added to a 250 ml round bottom three-neck flask under nitrogen flow and heated to 70.0 to melt octadecylamine. 4342.4 mg of Ce(NO₃)₃.6H₂O and 0.725 mL of deionized water were added to the above reaction mixture. The mixture was heated to 175° and then annealed for 30 minutes to achieve homogeneity, following which the temperature was raised to 230° C. The release of a large amount of NO₂ vapors after 2 minutes at 230° C. suggest the completion of reaction. The obtained solution was subsequently air cooled. To avoid over pressurization of flask, the stopper was punctured with a needle, as mentioned earlier. The collected colloidal solution was cleaned with ethanol and hexane, similar to the process employed with the 5.3 nm CeO₂ quantum dots.

Device Fabrication. Each avalanche device utilized a p-i-n fabrication process developed n 2.5×2.5 in² ITO coated glass substrates. The p-i layers were deposited directly onto the ITO coated glass under high vacuum. The p-layer consisted of a 2 μm thermally evaporated inorganic electron blocking layer, followed by the thermal evaporation of stabilized vitreous selenium pellets, forming the 15 μm a-Se i-layer. A 110 nm film of low temperature, sputtered SiO₂ (provided by Hionix Inc.) was deposited across the a-Se surface as a passivating buffer layer. The solution-synthesized CeO₂ quantum dots described above were spun-coat at room temperature to form the n-layer. 30 mg/ml dispersion of CeO₂ quantum dots was spun coat at 2000 rpm for 45 seconds, similarly the 50 mg/ml dispersion was spun coat at 1700 rpm for 45 seconds. Assembled CeO₂ quantum dot film were ligand exchanged with 130 mM (1% w/v) solution of ammonium thiocyanate (NH4SCN) in acetone followed by the spin coating of pure acetone with the same spin parameters as CeO₂, to remove unbound NH₄SCN.

The thin film deposition of CeO₂ quantum dots and ligand exchange was repeated twice to achieve desired thickness. Transparent ITO high voltage electrodes were patterned by a shadow mask and deposited via oxygen assisted electron beam deposition. Following the completion of wire bonding to the ITO based readout and high voltage electrodes, the entire device was encapsulated with parylene to prevent high voltage effects on the top surface.

Photoconductivity Measurement. For each measurement, a CAEN N1471A programmable high voltage power supply was used to positively bias the top electrode of the avalanche a-Se devices. The time (I-t) and voltage (I-V) dependent dark current characteristics were measured with a Keithley 6514 electrometer. Charge transport characteristics and avalanche gain were measured through optical TOF transient experiments using a 450 nm pulsed LED source with a 170 ns FWHM, driven by a Tektronix AFG 3021B function generator. The induced photocurrent was captured by a Tektronix TDS 7104 digital oscilloscope. Tektronix P6245 active probes were utilized to protect against device failure at high fields. For all photocurrent measurements of avalanche gain, the a-Se devices were mounted in a light tight, grounded metal box.

While the present invention has been particularly shown and described with respect to preferred embodiments thereof, it will be understood by those skilled in the art that the foregoing and other changes in forms and details may be made without departing from the spirit and scope of the present invention. It is therefore intended that the present application not be limited to the exact forms and details described and illustrated, but fall within the scope of the appended claims.

What is claimed is:

1. A photomultiplier comprising:
an electron-blocking layer located on a first electrode;
an amorphous selenium solid-state photoconductive film located on the electron-blocking layer;
a hole-blocking layer located on the amorphous selenium solid-state photoconductive film, wherein the hole-blocking layer comprises a non-insulating metal oxide; and
a second electrode located on the hole-blocking layer.

2. The photomultiplier of claim 1, further comprising a passivation buffer layer sandwiched between the amorphous selenium solid-state photoconductive film and the hole-blocking layer.

3. The photomultiplier of claim 1, wherein the first electrode is located on a surface of a substrate.

4. The photomultiplier of claim 1, wherein the first electrode, the electron-blocking layer, the amorphous selenium solid-state photoconductive film, the hole-blocking layer and the second electrode are vertically stacked one atop the other.

5. The photomultiplier of claim 1, wherein the amorphous selenium solid-state photoconductive film is entirely amorphous.

6. The photomultiplier of claim 1, wherein the non-insulating metal oxide has a dielectric constant of greater than 10 and is composed of metal oxide nanocrystals.

7. The photomultiplier of claim 6, wherein the metal oxide nanocrystals comprise cerium oxide quantum dots.

8. The photomultiplier of claim 1, wherein the non-insulating metal oxide has a dielectric constant of greater than 10 and is composed of a perovskite.

9. The photomultiplier of claim 8, wherein the perovskite comprises strontium titanate or barium titanate.

10. The photomultiplier of claim 1, wherein the non-insulating metal oxide is a nanocrystalline metal oxide.

11. An apparatus comprising:
at least one photomultiplier, wherein the at least one photomultiplier comprises an electron-blocking layer located on a first electrode, an amorphous selenium solid-state photoconductive film located on the electron-blocking layer. a hole-blocking layer located on the amorphous selenium photoconductive film, wherein the hole-blocking layer comprises a non-insulating metal oxide, and a second electrode located on the hole-blocking layer.

12. The apparatus of claim 11, further comprising a passivation buffer layer sandwiched between the amorphous selenium solid-state photoconductive film and the hole-blocking layer.

13. The apparatus of claim 11, wherein the non-insulating metal oxide has a dielectric constant of greater than 10 and is composed of metal oxide nanocrystals.

14. The apparatus of claim 13, wherein the metal oxide nanocrystals comprise cerium oxide quantum dots.

15. The apparatus of claim 13, wherein the non-insulating metal oxide has a dielectric constant of greater than 10 and is composed of a perovskite.

16. The apparatus of claim 15, wherein the perovskite comprises strontium titanate or barium titanate.

17. A method of forming a photomultiplier, the method comprising:
forming an electron-blocking layer located on a first electrode;
forming an amorphous selenium solid-state photoconductive film on the electron-blocking layer;
forming a hole-blocking layer on the amorphous selenium solid-state photoconductive film, wherein the hole-blocking layer comprises a non-insulating metal oxide; and
forming a second electrode on the hole-blocking layer.

18. The method of claim 17, wherein the forming the hole-blocking layer comprises:
preparing a solution processed material comprised of metal oxide nanocrystals or a perovskite; and
depositing, at a temperature less than a crystallization on-set temperature for selenium, the solution processed material on a surface of the amorphous selenium solid-state photoconductive film.

19. The method of claim 18, wherein the solution processed material comprises a colloidal dispersion of cerium oxide nanocrystals, and the depositing of the colloidal dispersion of cerium oxide nanocrystals provides a layer of cerium oxide quantum dots, and wherein the layer of cerium oxide quantum dots is further subjected to a ligand exchange process to form the hole-blocking layer.

20. The method of claim 18, wherein the temperature of the deposition is performed at nominal room temperature.
